(19) United States
(12) Patent Application Publication
(10) Pub. No.: US 2018/0314369 A1
(43) Pub. Date: Nov. 1, 2018

(54) DEVICE FOR TOUCH PANEL

(71) Applicant: SHARP KABUSHIKI KAISHA, Sakai City, Osaka (JP)

(72) Inventors: YUHJI YASHIRO, Sakai City (JP); YASUHIRO SUGITA, Sakai City (JP)

(21) Appl. No.: 15/769,970

(22) PCT Filed: Oct. 18, 2016
(86) PCT No.: PCT/JP2016/080825

§ 371 Date: Apr. 20, 2018

(30) Foreign Application Priority Data
Oct. 21, 2015 (JP) 2015-207146

(51) Int. Cl. G06F 3/047; G06F 3/044; H01L 21/768; H01Q 1/22

(52) U.S. Cl. CPC G06F 3/047; G06F 3/044; G06F 2203/04103; H01Q 1/2283; G06F 2203/04112; H01L 21/76892

(57) ABSTRACT

Provided is a device for touch panel characterized in that the deterioration of the performance of an antenna due to eddy current generated between the antenna and a touch sensor (electrodes for touch panel) can be prevented, and that the manufacturing cost can be reduced. A touch-panel-equipped display device 100 includes a coexisting conductive layer L_Y_Ant and an X-axis-direction electrode layer L_X. The coexisting conductive layer L_Y_Ant includes first sensor electrode patterns for touch panel and an antenna pattern. The X-axis-direction electrode layer L_X includes second sensor electrode patterns for touch panel that is arranged so as to intersect with the first sensor electrode patterns when viewed in a plan view.

### TECHNICAL FIELD

The present invention relates to a device for touch panel, the device including antenna patterns for short-range wireless communication in a region where an image or the like is to be displayed (display area).

### BACKGROUND ART

In recent years, the following technique is often used: between an IC card (contactless IC card) that does not include a power source and incorporates an antenna element for wireless communication, and a communication device that includes a power source, short-range communication is performed between the IC card and the communication device without the two being brought into contact with each other. For example, in a case where wireless communication (short-range communication) is performed between a communication device and a contactless IC card, the contactless IC card is brought close to the communication device, to such an extent that the distance between the antenna element of the communication device and the contactless IC card is equal to or less than a predetermined distance. The communication device includes a power source, and power is supplied to the antenna element for short-range wireless communication incorporated in the communication device, whereby a magnetic field is generated by the antenna element. Then, by the magnetic field generated by the communication device when the contactless IC card is brought close to the communication device, induced current is caused to flow through the antenna element of the contactless IC card. Thus, electric power can be supplied from the communication device to the contactless IC card. Then, the contactiess IC card causes a circuit (for example, an IC chip) in the contactless IC card to operate, with use of the electromotive force generated by the induced current. In this way, by bringing a contactless IC card close to a communication device, wireless communication (short-range communication) can be performed between the contactless IC card and the communication device.

Commonly, an antenna element is often made of a metal having a high conductivity (copper or silver) in order to ensure conductivity. Such a metal does not transmit light, and therefore, if the antenna element is formed in the display section of a display device that displays an image or a video image, light that forms an image or a video image is blocked by the antenna element.

To solve such a problem, Patent Document 1, for example, discloses a technique of forming mesh-type antenna patterns on a transparent substrate so as to ensure both of the conductivity for realizing the antenna function and the transparency.

### PRIOR ART DOCUMENT

### Patent Document

Patent Document 1: JP-A-2011-066610

### SUMMARY OF THE INVENTION

### Problem to be Solved by the Invention

For example, in a case where an antenna is mounted on a touch-panel-equipped display device with use of the above-described technique, the touch-panel-equipped display device may have a configuration that includes a first electrode layer in which X-axis-direction sense electrodes for touch panel are formed, a second electrode layer in which Y-axis-direction sense electrodes for touch panel (Y-axis-direction sense electrodes that are arranged so as to intersect with the X-axis-direction sense electrodes when viewed in a plan view) are formed, and a conductive layer for antenna pattern in which antenna patterns are formed.

FIG. 16 illustrates a schematic configuration of a touch-panel-equipped display device 900 in a case where the above-described technique is used. Here, it is assumed that the X axis and the Y axis are set as illustrated in FIG. 16.

The upper view in FIG. 16 is a plan view of the touch-panel-equipped display device 00, and the lower view in FIG. 16 is an A-A cross-sectional view of the same taken along line A-A. An area AR1 illustrated in the upper view in FIG. 16 is a display area (display surface) (in which an image or the like is displayed).

As illustrated in FIG. 16, the touch-panel-equipped display device 900 includes a case 91, a circuit part 92, a display panel DP, a conductive layer L_Ant for antenna pattern, a second electrode layer (Y-axis-direction electrode layer) L_Y, a first electrode layer (X-axis-direction electrode layer) L_X, and a cover 94.

FIG. 17 illustrates a plan view (upper view) of the first electrode layer (X-axis-direction electrode layer) L_X of the touch-panel-equipped display device 900, a plan view (middle view) of the second electrode layer (Y-axis-direction electrode layer) L_Y of the touch-panel-equipped display device 900, a plan view (lower view) of the conductive layer L_Ant for antenna pattern.

The first electrode layer (X-axis-direction electrode layer) L_X includes eight conductive patterns Ex1 to Ex8 formed on a substrate made of an insulation material (for example, PET (polyethylene terephthalate)), as illustrated in FIG. 17. Each of the conductive patterns Ex1 to Ex8 has a long and narrow shape that extends in the horizontal direction (X axis direction).

The second electrode layer (Y-axis-direction electrode layer) L_Y includes fourteen conductive patterns Ey1 to Ey14 formed on a substrate made of an insulation material (for example, PET (polyethylene terephthalate)), as illustrated in FIG. 17. Each of the conductive patterns Ey1 to Ey14 has a long and narrow shape extending in the vertical direction (Y axis direction).

The conductive layer L_Ant for antenna pattern includes an antenna pattern Ant formed on a substrate made of an insulation material (for example, PET (polyethylene terephthalate)), as illustrated in FIG. 17. The antenna pattern Ant has two terminals P1, P2, as illustrated in FIG. 16, and the terminals P1, P2 are connected to a matching unit (for example, matching adjustment circuit) that performs matching adjustment.

FIG. 18 illustrates an equivalent circuit of the first electrode layer (X-axis-direction electrode layer) L_X of the touch-panel-equipped display device 900, an equivalent circuit of the second electrode layer (Y-axis-direction electrode layer) L_Y of the touch-panel-equipped display device 900, an equivalent circuit of the conductive layer L_Ant for antenna pattern, and an equivalent circuit of the display panel DP. In the equivalent circuit of the conductive layer L_Ant for antenna pattern in FIG. 18, a matching unit M1 is connected to end points P1, P2 of the antenna pattern Ant, and further, an antenna driving unit AD1 is connected to the matching unit M1.

In a case where the touch-panel-equipped display device 900 is formed by using the prior art in this way, there are the following problems. As illustrated in 18, when the antenna Ant is driven, a magnetic field that is generated due to an inductance L in the conductive layer L_Ant for antenna pattern causes eddy current to be generated in a coil Lx in the first electrode layer (X-axis-direction electrode layer) L_X, a coil Ly in the second electrode layer (Y-axis-direction electrode layer) L_Y, and a coil Ldp in the display panel DP. This causes antenna properties to deteriorate, and further causes the amount of consumption of electric power for antenna driving to increase. Still further, in a case where the touch-panel-equipped display device 900 is formed by using the prior art, it is necessary to provide a conductive layer for forming an antenna pattern Ant additionally, which causes the manufacturing cost to rise.

In light of the above-described problems, it is an object of the present invention to realize a device for touch panel characterized in that the deterioration of the performance of an antenna due to eddy current generated between the antenna and a touch sensor (electrodes for touch panel) can be prevented, and that the manufacturing cost can be reduced.

### Means to Solve the Problem

To achieve the above-described object, a first configuration is a device for touch panel that includes a first electrode layer and a second electrode layer.

The first electrode layer includes a first sensor electrode pattern for ouch panel and an antenna pattern.

The second electrode layer includes a second sensor electrode pattern for touch panel that is arranged so as to intersect with the first sensor electrode pattern when viewed in a plan view.

### Effect of the Invention

The present invention makes it possible to realize a device for touch panel characterized in that the deterioration of the performance of an antenna due to eddy current generated between the antenna and a touch sensor (electrodes for touch panel) can be prevented, and that the manufacturing cost can be reduced.

### BRIEF DESCRIPTION OF DRAWINGS

FIG. 1 illustrates a schematic configuration of a touch-panel-equipped display device 100 according to Embodiment 1.

FIG. 2 is a plan view of a coexisting electrode layer L_Y_Ant.

FIG. 3A is a plan view of the coexisting electrode layer L_Y_Ant.

FIG. 3B is an enlarged view of a part of a plan view of the coexisting electrode layer L_Y_Ant (a plan view when it is viewed from above the display surface).

FIG. 3C is a plan view of the coexisting electrode layer L_Y_Ant (a plan view when it is viewed from above the display surface) in a case where Y-axis-direction electrode patterns are formed thinner and narrower.

FIG. 4 is a plan view of an X-axis-direction electrode layer L_X.

FIG. 5 illustrates an equivalent circuit of an X-axis-direction electrode layer L_X of a touch-panel-equipped display device 100, an equivalent circuit of a coexisting conductive layer L_Y_Ant of the touch-panel-equipped display device 100, and an equivalent circuit of a display panel DP.

FIG. 6 is a plan view of a coexisting electrode layer L_Y_Ant of a touch-panel-equipped display device according to Modification Example 1 of Embodiment 1.

FIG. 7 is a plan view of a coexisting electrode layer L_Y_Ant of a touch-panel-equipped display device according to Modification Example 2 of Embodiment 1.

FIG. 8 is a plan view of a coexisting electrode layer L_Y_Ant of a touch-panel-equipped display device according to Modification Example 3 of Embodiment 1.

FIG. 9 illustrates a schematic configuration of antenna patterns Ant_p1, Ant_p2, Ant_p3, and Ant_p4 formed in a coexisting electrode layer L_Y_Ant of a touch-panel-equipped display device according to Modification Example 4 of Embodiment 1, and a flexible printed substrate FPC1 in a two-layer structure.

FIG. 10 illustrates a schematic configuration of antenna patterns Ant_p1, Ant_p2, Ant_p3, and Ant_p4 formed in a coexisting electrode layer L_Y_Ant of a touch-panel-equipped display device according to Modification Example 4 of Embodiment 1, and a flexible printed substrate FPC1.

FIG. 11 illustrates a schematic configuration of antenna patterns Ant_p1, Ant_p2, Ant_p3, and Ant_p4 formed in a coexisting electrode layer L_Y_Ant of a touch-panel-equipped display device according to Modification Example 4 of Embodiment 1, and a flexible printed substrate FPC1.

FIG. 12 illustrates a schematic configuration of antenna patterns Ant_p1, Ant_p2, Ant_p3, and Ant_p4 formed in a coexisting electrode layer L_Y_Ant of a touch-panel-equipped display device according to Modification Example 4 of Embodiment 1, and a flexible printed substrate FPC1.

FIG. 13 illustrates a schematic configuration of antenna patterns Ant_p1 Ant_p2, Ant_p3, and Ant_p4 formed in a coexisting electrode layer L_Y_Ant of a touch-panel-equipped display device according to Modification Example 4 of Embodiment 1, and a flexible printed substrate FPC1.

FIG. 14 is a perspective view illustrating a schematic configuration of an X-axis-direction electrode layer LX and a coexisting conductive layer L_Y_Ant in a touch-panel-equipped display device of Modification Example 5.

FIG. 15 is a perspective view illustrating a schematic configuration of an X-axis-direction electrode layer L_X, a coexisting conductive layer L_Y_Ant, and an antenna layer L_Ant in a touch-panel-equipped display device of Modification Example 6.

FIG. 16 illustrates a schematic configuration of a touch-panel-equipped display device 900.

FIG. 17 illustrates a plan view (upper view) of a first electrode layer (X-axis-direction electrode layer) L_X of the touch-panel-equipped display device 900, a plan view (middle view) of a second electrode layer (Y-axis-direction electrode layer) L_Y of the touch-parcel-equipped display device 900, and a plan view (lower view) of a conductive layer L_Ant for antenna pattern.

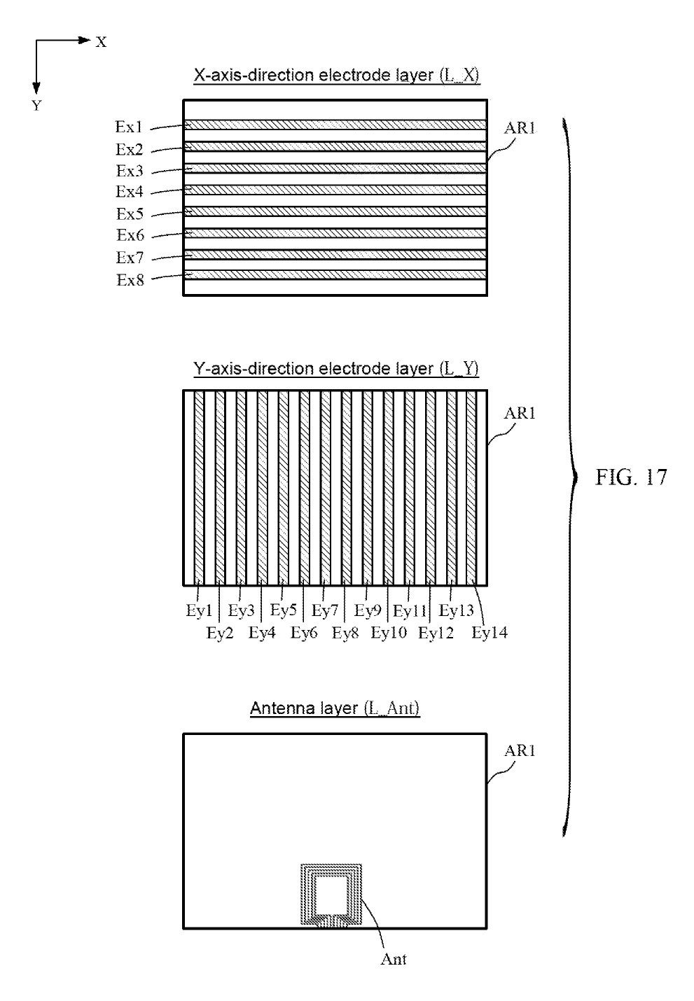

FIG. 18 illustrates an equivalent circuit of the first electrode layer (X-axis-direction electrode layer) L_X of the touch-panel-equipped display device 900, an equivalent circuit of the second electrode layer (Y-axis-direction electrode layer) L_Y of the touch-panel-equipped display device 900, an equivalent circuit of the conductive layer L_Ant for antenna pattern, and an equivalent circuit of a display panel DP.

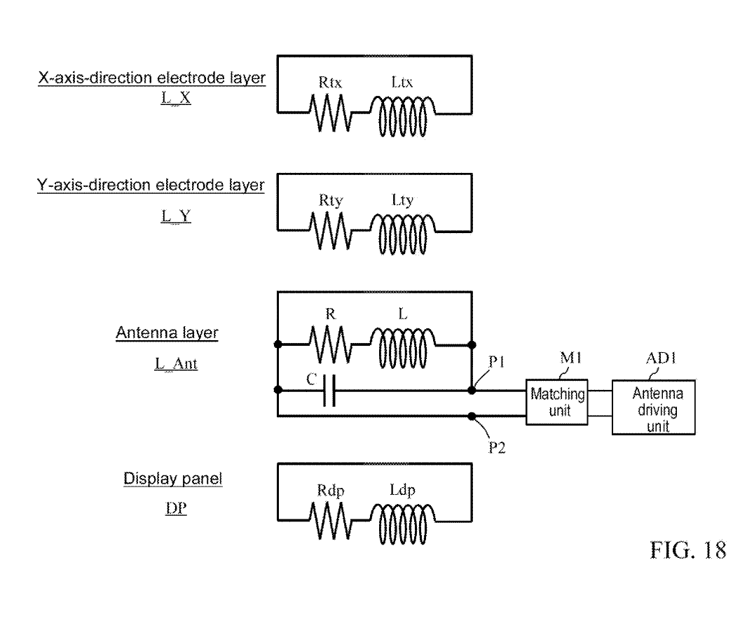

### MODE FOR CARRYING OUT THE INVENTION

### Embodiment 1

The following description describes Embodiment 1 while referring to the drawings.

### <1.1: Configuration of Touch-Panel-Equipped Display Device>

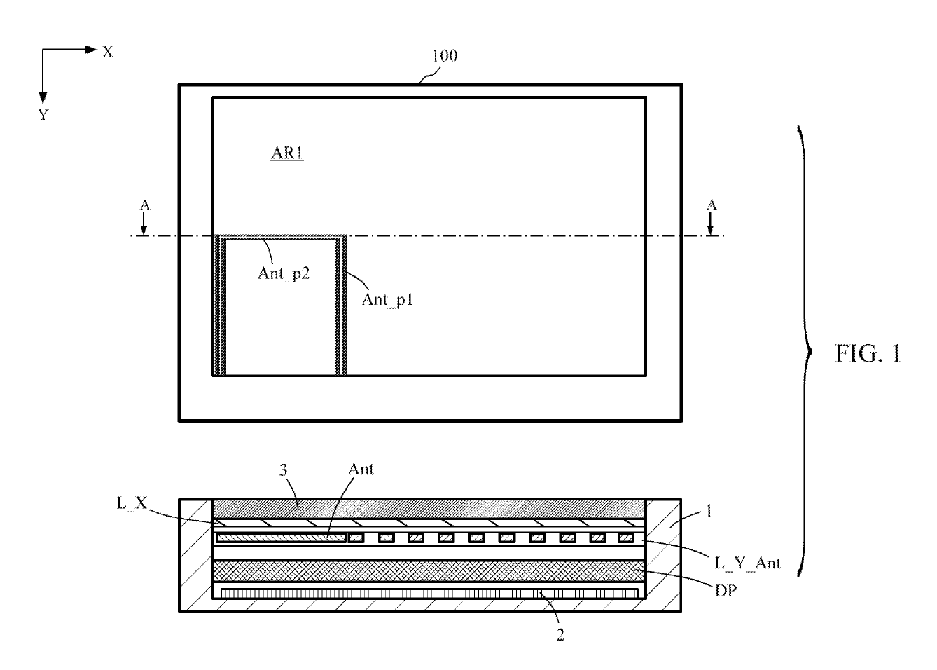

FIG. 1 is a diagram (one example) schematically illustrating a schematic configuration of a touch-panel-equipped display device 100 (an exemplary device for touch panel) according to Embodiment 1. More specifically, FIG. 1 illustrates a plan view of a touch-panel-equipped display device 100 (a plan view of the device when it is viewed from above the display surface) (upper view), and an A-A cross-sectional view (lower view) taken along line A-A.

The touch-panel-equipped display device 100 includes a case 1, a circuit part 2, a display panel DP, a coexisting conductive layer L_Y_Ant (a conductive layer in which antenna patterns and Y-axis-direction electrodes coexist), an X-axis-direction, electrode layer X, and a cover 3, as illustrated in FIG. 1.

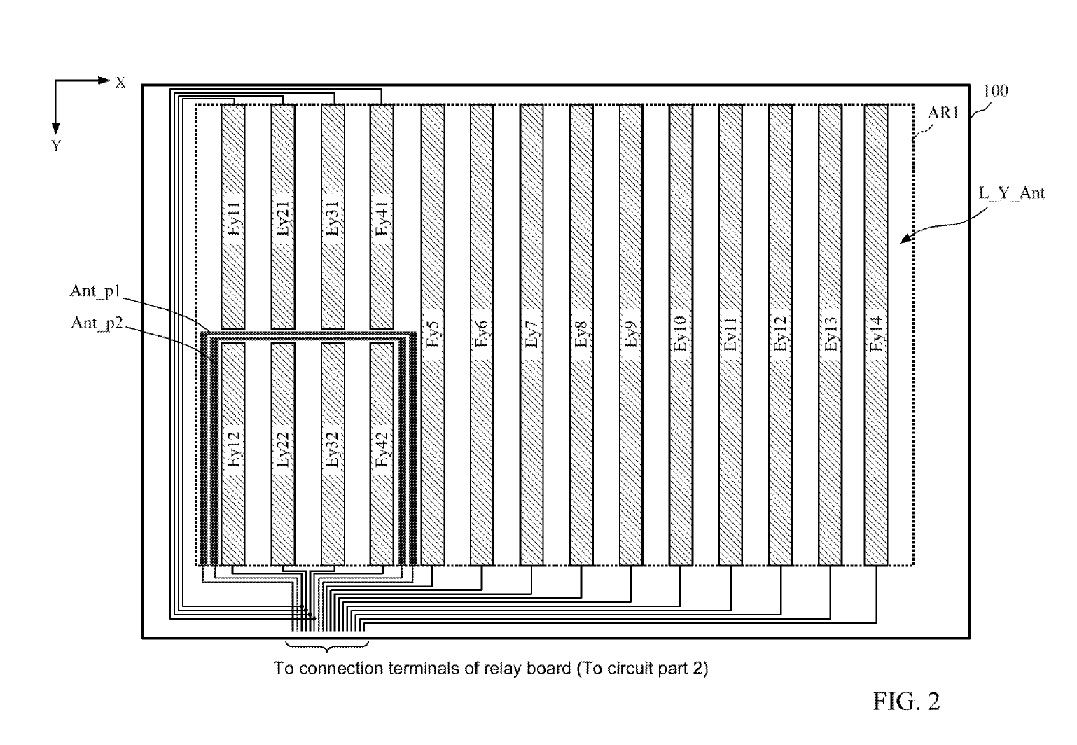

FIG. 2 is a plan view of the coexisting electrode layer L_Y_Ant (a plan view of the same when it is viewed from above the display surface).

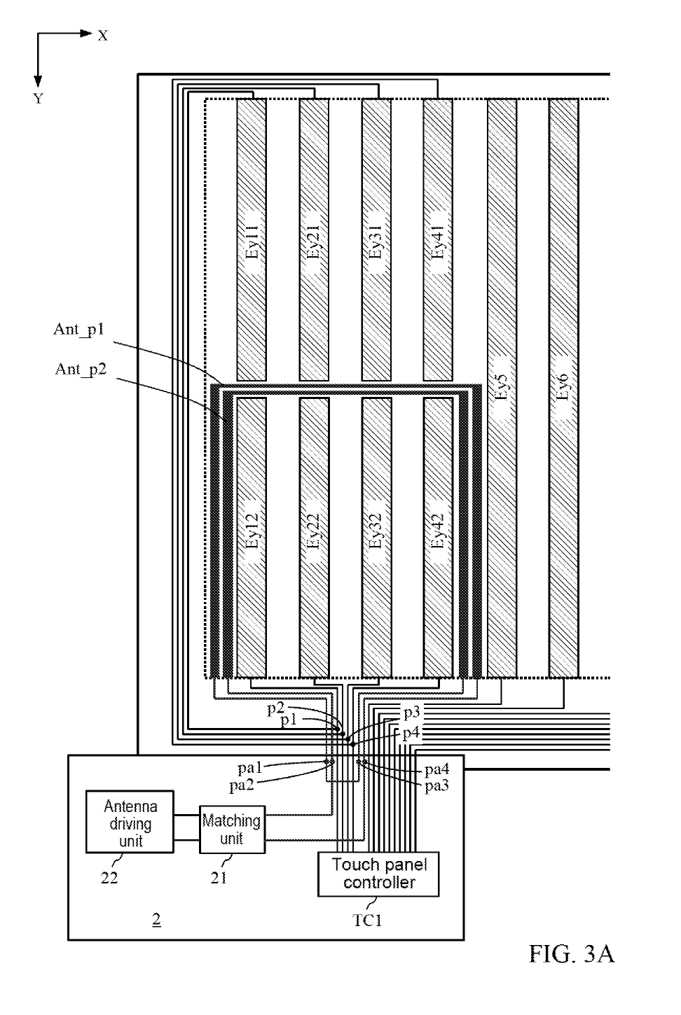

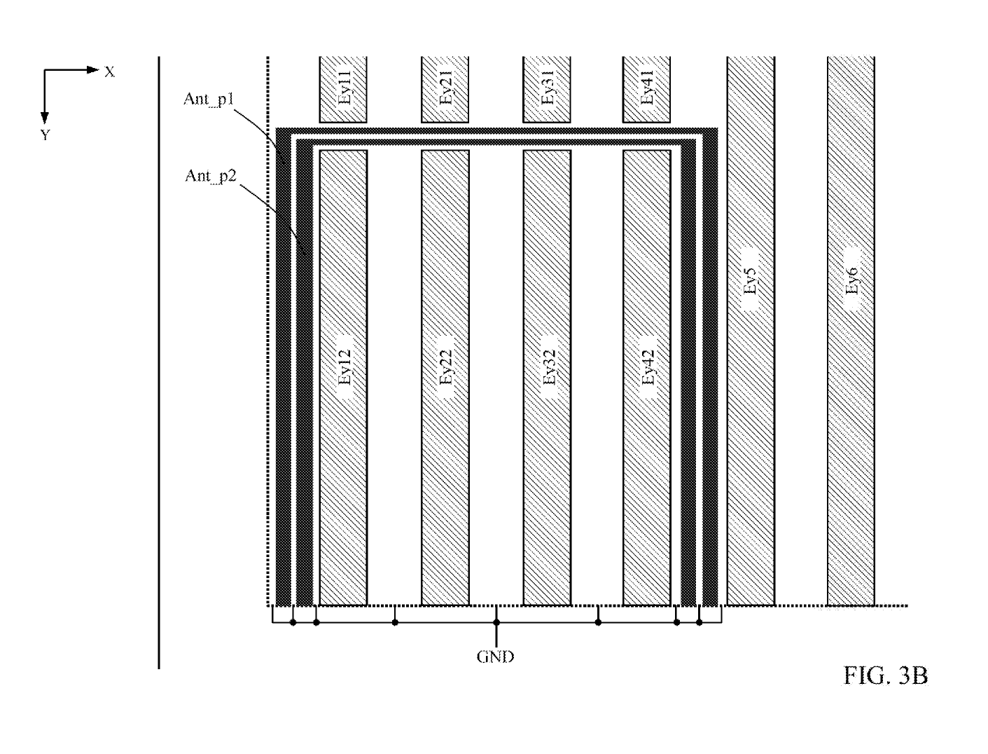

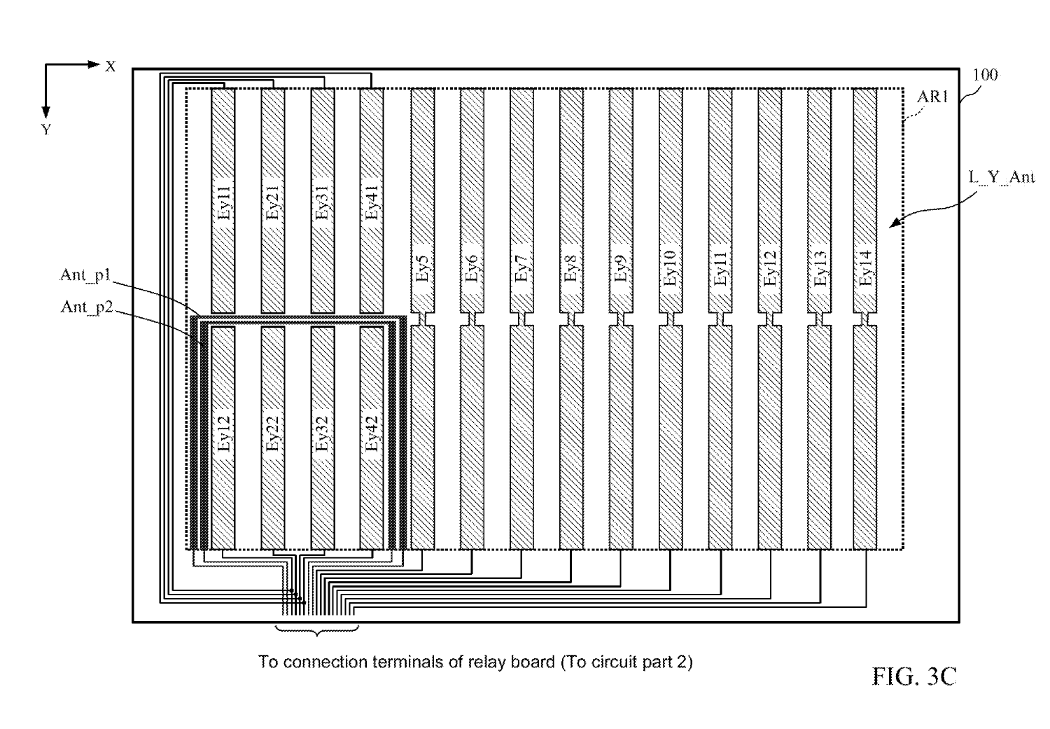

FIG. 3A schematically illustrates a part of a plan view of the coexisting electrode layer L_Y_Ant (a plan view of the same When it is viewed from above the display surface), and a schematic configuration of a part of the circuit part 2.

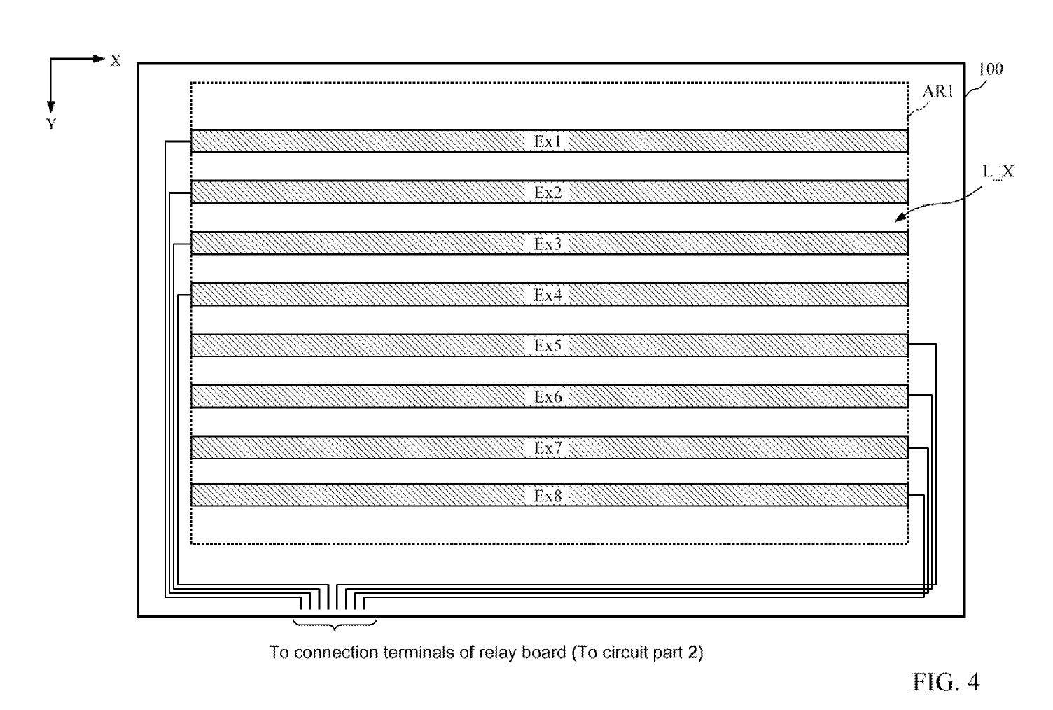

FIG. 4 is a plan view of the X-axis-direction electrode layer L_X (a plan view of the same when it is viewed from above the display surface).

As illustrated in FIG. 1, the case 1 is configured so as to be able to house therein the circuit part 2 including a circuit board, a battery, and the like, the display panel DP (for example, a liquid crystal display panel device), the coexisting conductive layer L_Y_Ant, and the X-axis-direction electrode layer L_X.

Further, as illustrated in FIG. 1, a transparent cover 6 (a cover 6 formed with an insulation material) is attached to the case 1. so that dirt, dust and the like is prevented from entering the inside.

The circuit part 2 includes a circuit board, and various types of circuits are formed on the circuit board. The circuit part 2 includes, for example, a matching unit 21 and an antenna driving unit 22, as illustrated in FIG. 3A. Further, the circuit part 2 includes, for example, a touch panel controller TC1, as illustrated in FIG. 3A.

The touch panel controller TC1 sequentially outputs a drive actuating signal o the X-axis-direction electrodes Ex1 to Ex8 formed in the X-axis-direction electrode layer L_X illustrated in FIG. 4, to cause electric fields to be generated between the X-axis-direction electrodes Ex1 to Ex8 and the Y-axis-direction electrodes Ey11 to Ey41, Ey21 to Ey42, Ey5 to Ey14 illustrated in FIG. 3A. Then, the touch panel controller TC1 receives sense signals that have signal values corresponding to electric field changes, respectively, from sense lines (connection lines) that are connected to the Y-axis-direction electrodes Ey11 to Ey41, Ey21 to Ey42, Ey5 to Ey14, and detects a position of a touch point, which is a point touched by a finger, a pen, or the like in an area AR1 (on the touch panel surface), based on the received sense signals,

Further, the circuit part 2 includes, for example, a display panel control unit (not shown) for controlling the display panel DP.

The matching unit 21 includes a circuit that performs impedance adjustment (an impedance adjustment circuit) and the like. The impedance adjustment circuit of the matching unit 21 is connected with antenna patterns Ant_p1, Ant_p2 formed in the coexisting conductive layer L_Y_Ant through terminals pa2, pa4 for connection (terminals pa2, pa4 for connection, illustrated in FIG. 3A), to perform the impedance adjustment.

The antenna driving unit 22 is connected with the matching unit 21, as illustrated in FIG. 3A. The antenna driving unit 22 drives the antenna patterns Ant_p1, Ant_p2 formed in the coexisting conductive layer L_Y_Ant through the matching unit 21. The antenna driving unit 22 outputs an RF signal generated by performing a modulation processing operation with respect to a predetermined carrier wave frequency by a predetermined modulation method, via the matching unit 21, to the antenna patterns Ant_p1, Ant_p2 formed in the coexisting conductive layer L_Y_Ant. Besides, the antenna driving unit 22 executes a predetermined demodulation processing operation to an RF signal received through the antenna patterns Ant_p1, Ant_p2 formed in the coexisting conductive layer L_Y_Ant, and the matching unit 21, and acquires a signal (data and the like) contained in the received RF signal.

The display panel DP is, for example, a display panel in which liquid crystal, organic EL, or the like is used (a liquid crystal display panel or an organic EL display panel). The display panel DP is connected to a display panel control unit (not shown), so that the display panel DP is driven and controlled by the display panel control unit. With the driving of the display panel DP controlled by the display panel control unit, an image of the like, for example, is displayed on the display panel DP.

As illustrated in FIG. 1, the display panel DP is arranged, when viewed in the cross section, between the circuit part 2 in which the circuit board, the battery and the like are housed, and the transparent cover 3 (for example, a cover 3 made of transparent glass or the like).

The coexisting conductive layer L_Y_Ant (the coexisting conductive layer in which antenna patterns and the Y-axis-direction electrodes coexist) includes the antenna patterns Ant_p1, Ant_p2, and the Y-axis-direction electrode patterns Ey1 to Ey41, Ey21 to Ey42, Ey5 to Ey14, formed on a substrate made of an insulation material (for example, PET (polyethylene terephthalate)), as illustrated in FIGS. 1 to 3A. Each of the Y-axis-direction electrode patterns Ey1 to Ey41, Ey21 to Ey42, Ey5 to Ey14 has a long and narrow shape extending in the vertical direction (Y axis direction), as illustrated in FIG. 2. Besides, areas where parts extended in the X axis direction of the antenna patterns Ant_p1, Ant_p2 can be arranged are provided, as illustrated in FIG. 2, in a space between the Y-axis-direction electrode patterns Ey11 and Ey12, a space between the Y-axis-direction electrode patterns Ey21 and Ey22, a space between the Y-axis-direction electrode patterns Ey31 and Ey32, and a space between the Y-axis-direction electrode patterns Ey41 and Ey42.

Here, in blank areas (areas where the Y direction electrodes are not formed) in the area AR1 illustrated in in FIG. 2, desirably, dummy patterns are arranged. By arranging dummy patterns in this way, it is possible to appropriately prevent electrode patterns for touch panel and electrode patterns for antenna from being visualized when the display surface of the touch-panel-equipped display device 100 is viewed with the transmittance being uniform over the surface (over the entire display surface).

Further, the dummy patterns are in an electrically floating state, or alternatively, are electrically connected so as to have a certain set potential (for example, a GND potential). The dummy patterns are in a state in which a voltage is applied to the same. The dummy patterns, however, are preferably connected to GND.

This is intended to make approximately equal the intersection capacitances between the X-axis-direction electrodes and the Y-axis-direction electrodes in areas where the antenna patterns (antenna electrodes) are present and such intersection capacitances in the areas where no antenna pattern are present. Consequently, the touch panel performance is improved.

to make equal the intersection capacitances between the Y-axis-direction electrode patterns and the X-axis-direction electrode patterns in the areas where the antenna patterns are present and such intersection capacitances in the areas where the antenna patterns are not present. Consequently, the performance of the touch panel can be improved.

Further, by connecting the dummy patterns to the GND potential, the values of coupling capacitances between the antenna patterns (antenna electrodes) and the Y-axis-direction electrodes for touch panel can be reduced, whereby antenna noise that is propagated from the antenna patterns (antenna electrodes) to the Y-axis-direction electrodes can be suppressed. This makes it possible to improve the performance of the touch panel.

In the case of the above-described configuration, the width of the dummy pattern (the width of the pattern connected to the GND potential) is desirably 300 μm or more.

The antenna patterns Ant_p1, Ant_p2 are, for example, transparent conductive patterns (transparent electrodes) made of ITO or the like. Alternatively, the antenna patterns Ant_p1, Ant_p2 may be formed with mesh patterns of thin metal lines (for example, copper lines). Forming the antenna patterns Ant_p1, Ant_p2 in this way makes it possible to ensure that light should not be blocked by the antenna patterns Ant_p1, Ant_p2 (to ensure certain light transmissivity).

The Y-axis-direction electrode patterns Ey1 to Ey41, Ey21 to Ey42, Ey5 to Ey14 are, for example, transparent conductive patterns (transparent electrodes) made of ITO or the like. Alternatively, the Y-axis-direction electrode patterns Ey1 to Ey41, Ey21 to Ey42, Ey5 to Ey14 may be formed with mesh patterns of thin metal lines (for example, copper lines). Forming the Y-axis-direction electrode patterns Ey1 to Ey41, Ey21 to Ey42, Ey5 to Ey14 in this way makes it possible to ensure that light should not be blocked by the Y-axis-direction electrode patterns Ey1 to Ey41, Ey21 to Ey42, Ey5 to Ey14 (to ensure certain light transmissivity).

As illustrated in. FIGS. 2 and 3A, a conducting line connected to the Y-axis-direction electrode pattern Ey11, and a conducting line connected to the Y-axis-direction electrode pattern Ey12, are connected at a contact point p1, whereby the Y-axis-direction electrode patterns Ey11 and Ey12 are electrically connected. Further, the Y-axis-direction electrode patterns Ey11 and Ey12 are connected to the touch panel controller TC1, as illustrated in FIG. 3A.

As illustrated in FIGS. 2 and 3A, a conducting line connected to the Y-axis-direction electrode pattern 421′, and a conducting line connected to the Y-axis-direction electrode pattern Ey22, are connected at a contact point p2, whereby the Y-axis-direction electrode patterns Ey21 and Ey22 are electrically connected. Further, the Y-axis-direction electrode patterns Ey21 and Ey22 are connected to the touch panel controller TC1, as illustrated in FIG. 3A.

As illustrated in FIGS. 2 and 3A, a conducting line connected to the Y-axis direction electrode pattern Ey31, and a conducting line connected to the Y-axis-direction electrode pattern Ey32, are connected at a contact point p3, whereby the Y-axis-direction electrode patterns Ey31 and Ey32 are electrically connected. Further, the Y-axis-direction electrode patterns Ey31 and Ey32 are connected to the touch panel controller TC1, as illustrated in FIG. 3A.

As illustrated in FIGS. 2 and 3A, a conducting line connected to the Y-axis-direction electrode pattern Ey41, and a conducting line connected to the Y-axis-direction electrode pattern Ey42, are connected at a contact point p4, whereby the Y-axis-direction electrode patterns Ey41 and Ey42 are electrically connected. Further, the Y-axis-direction electrode patterns Ey41 and Ey42 are connected to the touch panel controller TC1, as illustrated in FIG. 3A.

As illustrated in. FIGS. 2 and 3A, the Y-axis-direction electrode patterns Ey5 to Ey14 are respectively connected to the touch panel controller TC1 through conducting lines.

The antenna pattern Ant_p2 has an angular U-shape in a plan view, as illustrated in FIG. 2, and is arranged so as to surround the Y-axis-direction electrode patterns Ey12 to Ey42. As illustrated in FIGS. 2 and 3A, the antenna pattern Ant_p2 is connected to connection terminals pa2, pa3 for the antenna pattern Ant_p2, through conducting lines (or conductive patterns).

The antenna pattern Ant_p1 has an angular U-shape in a plan view, as illustrated in FIG. 2, and is arranged so as to surround the Y-axis-direction electrode patterns Ey12 to Ey42, and the antenna pattern Ant_P2. As illustrated in FIGS. 2 and 3A, the antenna pattern Ant_p1 is connected to connection terminals pa1, pa4 for the antenna pattern Ant_p1, through conducting lines (or conductive patterns).

As illustrated in FIG. 3A, the terminals pa1 and pa3 are connected by conducting lines, whereby a double helical antenna pattern (two-turn helical antenna pattern) is formed.

As illustrated in FIG. 3A, the terminals pa2 and pa4 are connected via conducting lines to the matching unit 21.

A GND electrode pattern may be provided so as to be along the antenna patterns Ant_p1, Ant_p1.

FIG. 3B is an enlarged view illustrating a part of the plan view of the coexisting electrode layer L_Y_Ant (when viewed from above the display surface).

As illustrated in FIG. 3B, a dummy area (a blank area in FIG. 38) between the antenna pattern Ant_p1 and the antenna pattern Ant_p2 may be connected to a GND potential.

Further, as illustrated in FIG. 3B, a dummy area (a blank area in FIG. 3B) that is an outer circumference area around the antenna pattern Ant_p1 and within the area AR1 may be connected to a GND potential.

Still further, as illustrated in FIG. 38, a dummy area (a blank area in FIG. 3B) between the antenna pattern Ant_p2 and the Y-axis-direction electrode pattern Ey12 may be connected to a GND potential.

Still further, as illustrated in FIG. 3B, a dummy area (a blank area in FIG. 3B) between the antenna pattern Ant_p2 and the Y-axis-direction electrode pattern Ey42 may be connected to a GND potential.

The configuration may be as follows: in the above-described dummy area, for example, a mesh pattern of thin metal lines is formed, and by connecting the mesh pattern in the above-described dummy area to a GND potential, the dummy area is connected to a GND potential.

Further, the above-described dummy area may be in a floating state (a state of being connected to no potential).

The connection method and the connection positions for the GND electrode patterns Gnd1 to Gnd4, however, are not limited to those illustrated in FIG. 3, and may be other connection method and connection positions.

Further, as illustrated in FIG. 3B, the configuration may be such that dummy areas between the Y-axis-direction electrode patterns Ey12, Ey22, Ey32, Ey42 are connected by one line. The dummy areas may have a GND potential thereby.

Still further, the configuration may be such that dummy areas around the Y-axis-direction electrode patterns Ey11, Ey21, Ey31, Ey41 are connected by one line. The dummy areas may have a GND potential thereby.

Still further, the configuration may be such that connection to dummy areas around the Y-axis-direction electrode patterns Ey5 to Ey14 are achieved from the terminal edge side of the touch panel TP (the side where the circuit part 2 is arranged), and from the side opposite to the foregoing side. This makes it possible to reduce the number of terminals.

Still further, it is preferable that the Y-axis-direction electrode patterns in areas where the antenna patterns are not arranged are formed thinner and narrower. This is intended to make approximately equal the intersection capacitances between the Y-axis-direction electrode patterns and the X-axis-direction electrode patterns in the areas where the antenna patterns are present and such intersection capacitances in the areas where no antenna patterns are present. Consequently, the performance of the touch panel can be improved.

Particularly, as indicated in Japanese Patent No. 4955116, in a case where the reading method of the touch panel controller is the differential reading method, when the Y-axis-direction electrode patterns are assumed to be sense electrodes (reception electrodes), intersection capacitances between the X-axis-direction electrode patterns and the Y-axis-direction electrode patterns are significantly different between the areas where the antenna patterns are present and the areas where no antenna patterns are present. This causes an amplified output to be saturated (when, for example, a difference between electric fields generated in the Y-axis-direction electrode patterns Ey41, Ey42 and the Y-axis-direction electrode pattern Ey5 (or voltages corresponding to the same) is determined), thereby causing the sensitivity of the touch panel to significantly deteriorate.

To prevent such a problem, it is preferable to make the Y-axis-direction electrode patterns thinner and narrower, to reduce a difference between the intersection capacitances.

FIG. 3C is a plan view of the coexisting electrode layer L_Y_Ant (a plan view when it is viewed from above the display surface) in a case where Y-axis-direction electrode patterns are formed thinner and narrower.

As illustrated in FIG. 3C, regarding the Y-axis-direction electrode patterns Ey5 to Ey14, the electrode patterns are narrower in an area where the antenna patterns extending in the Y axis direction are arranged. This makes it possible to reduce the difference between the intersection capacitances, as described above.

The X-axis-direction electrode layer L_X includes the X-axis-direction electrode patterns Ex1 to Ex8 formed on a substrate made of an insulation material (for example, PET (polyethylene terephthalate)), as illustrated in FIG. 4.

The X-axis-direction electrode patterns Ex1 to Ex8 are, for example, transparent conductive patterns (transparent electrodes) made of ITO or the like. Alternatively, the X-axis-direction electrode patterns Ex1 to Ex8 may be formed with mesh patterns of thin metal lines (for example, copper lines). Forming the X-axis-direction electrode patterns Ex1 to Ex8 in this way makes it possible to ensure that light should not be blocked by the X-axis-direction electrode patterns Ex1 to Ex8 (to ensure certain light transmissivity).

Each of the X-axis-direction electrode patterns Ex1 to Ex8, as illustrated in FIG. 4, has a long and narrow shape that extends in the horizontal direction (X axis direction). The X-axis-direction electrode patterns Ex1 to Ex8, as illustrated in FIG. 4, are respectively connected to the touch panel controller TC1 through conducting lines. The touch panel controller TC1 outputs a gate driving signal sequentially to the X-axis-direction electrode patterns Ex1 to Ex8, so as to sequentially drive the X-axis-direction electrode patterns Ex1 to Ex8. This causes electric fields to be generated between the X-axis-direction electrode patterns Ex1 to Ex8 and the Y-axis-direction electrode patterns Ey11 to Ey41, Ey12 to Ey42, Ey5 to Ey14. The touch panel controller TC1 receives sense signals through the conducting lines connected to the Y-axis-direction electrode patterns Ey11 to Ey41, Ey12 to Ey42, Ey5 to Ey14, and determines signal values of the sense signals. Thereby, a touch point (a point at which the electric field changes) on the surface of the touch panel can be detected.

The cover 3 is made of a transparent insulation material. The cover 3 is ins ailed on the case 1 as illustrated in FIG. 1, thereby preventing dirt, dust, and the like from entering the inside of the touch panel-equipped display device 100.

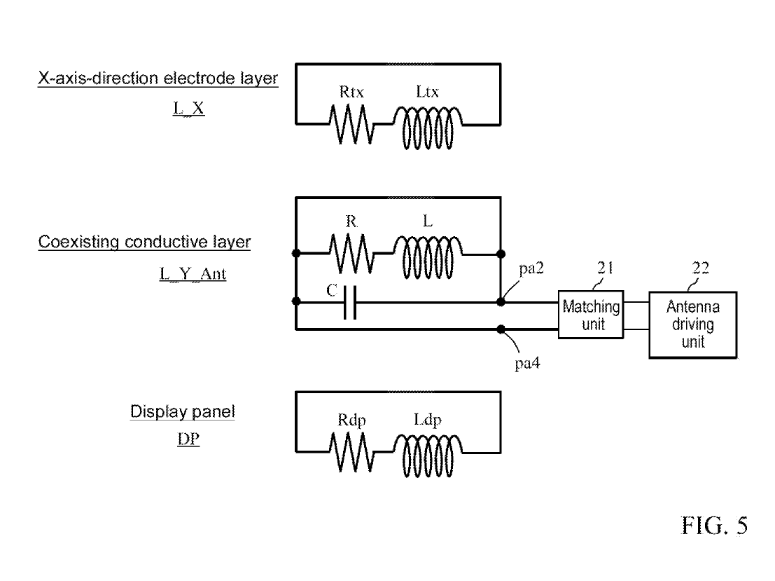

FIG. 5 illustrates an equivalent circuit of an X-axis-direction electrode layer L_X of a touch-panel-equipped display device 100, an equivalent circuit of a coexisting conductive layer L_Y_Ant of the touch-panel-equipped display device 100, and an equivalent circuit of a display panel DP. In the equivalent circuit of the coexisting conductive layer L_Y_Ant in FIG. 5, the matching unit 21 is connected to end points pa1, pa2 (end points pa1, pa2 illustrated in FIG. 3A), and further, the antenna driving unit 22 is connected to the matching unit 21.

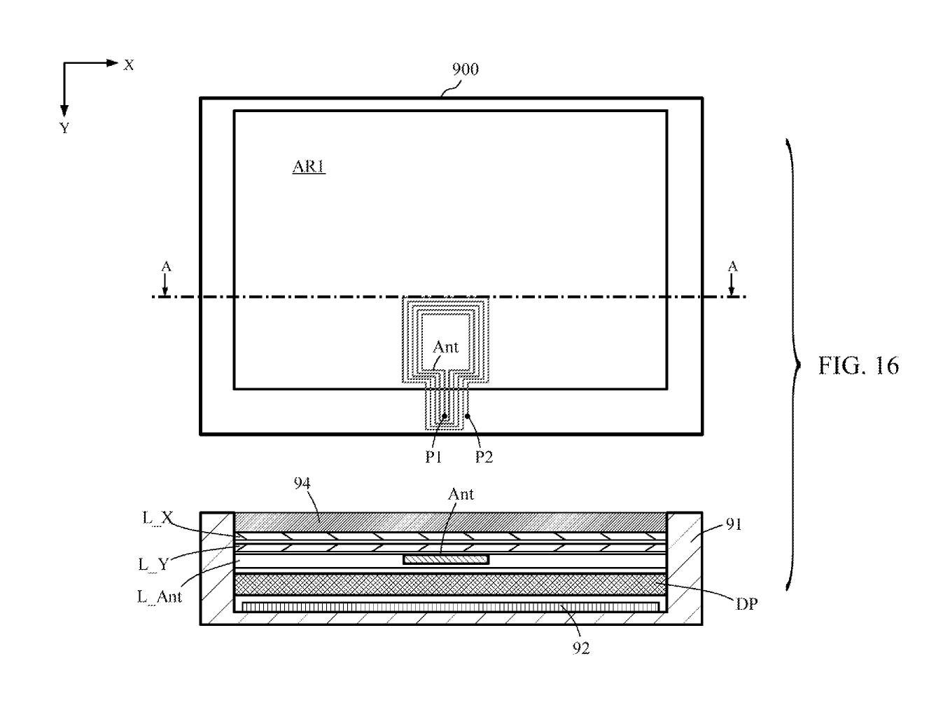

As is dear from FIG. 5, the touch-panel-equipped display device 100 does not include a coil Lty illustrated in FIG. 16, and therefore, such eddy current as that generated at the coil Lty can be eliminated therein, as compared with the case where the prior art is applied as illustrated in FIG. 16. In other words, in the touch-panel-equipped display device 100, both of the antenna patterns and the Y-axis-direction electrode patterns for touch panel are formed in the coexisting conductive layer L_Y_Ant, which makes it possible to suppress eddy current generated between the antenna and the touch sensor (electrodes for touch panel), as compared with a case where the prior art is applied. As a result, in the touch-panel-equipped display device 100, the deterioration of the performance of the antenna due to eddy current generated between the antenna and the touch sensor (electrodes for touch panel) can be prevented, as compared with a case where the prior art is applied.

Further, in the touch-panel-equipped display device 100, both of the antenna patterns and the Y-axis-direction electrode patterns for touch panel are formed in the coexisting conductive layer L_Y_Ant, which makes it unnecessary to additionally provide a layer in which antenna patterns are to be formed as in the case where the prior art is applied. Therefore, it is possible to reduce the manufacturing cost.

### Modification Example 1

The following description describes Modification Example 1 of the present embodiment.

The same parts as those described above are denoted by the same reference numerals, and detailed descriptions of the same are omitted.

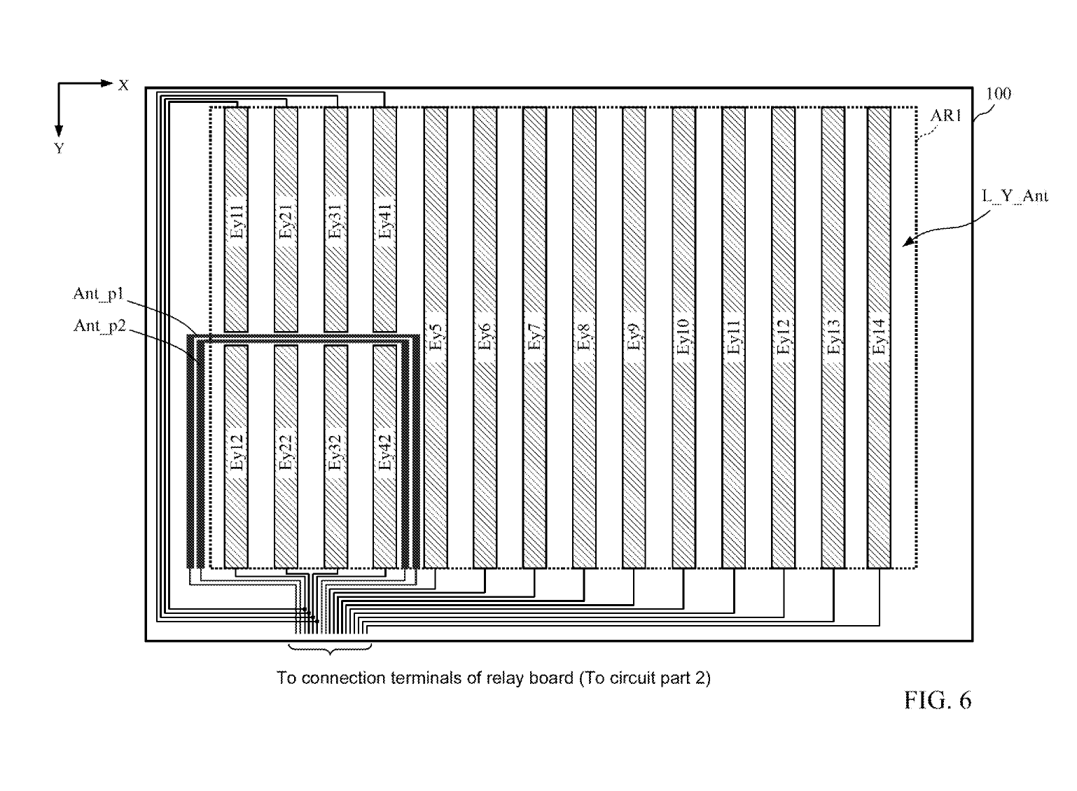

FIG. 6 is a plan view (a plan view when viewed from above the display surface) of a coexisting electrode layer L_Y_Ant of a touch-panel-equipped display device according to Modification Example 1.

In the touch-panel-equipped display device of Modification Example 1, as illustrated in FIG. 6, a part of antenna patterns Ant_p1, Ant_p2a of the coexisting electrode layer L_Y_Ant is formed in a frame area, which is an area outside the area AR1 (the display surface AR1). This is the point that makes the touch-panel-equipped display device of Modification Example 1 different from the touch-panel-equipped display device 100 of Embodiment 1. Regarding the other points, the touch-panel-equipped display device of Modification Example 1 is identical to the touch-panel-equipped display device 100 of Embodiment 1.

In the touch-panel-equipped display device of Modification Example 1, as illustrated in FIG. 6, parts of the antenna patterns Ant_p1, Ant_p2 in the coexisting electrode layer L_Y_Ant, extending in the Y axis direction outside the Y-axis-direction electrode pattern Ey12, are formed in a frame area that is an area outside the area AR1 (the display surface AR1).

With this configuration, areas that the antenna patterns Ant_p1, Ant_p2 occupy in the area AR1 (display surface AR1) can be reduced in the touch-panel-equipped display device of Modification Example 1. As a result, in the touch-panel-equipped display device of Modification Example 1, eddy current generated in another layer (the X-axis-direction electrode layer or the display panel DP) by an inductance component (the coil L in the equivalent circuit) in the coexisting electrode layer L_Y_Ant can be reduced. In the touch-panel-equipped display device of Modification Example 1 therefore, the deterioration of performance of the antenna caused by eddy current generated between the antenna and the touch sensor (electrodes for touch panel) can be further appropriately prevented.

Besides, using the frame area makes it possible to arrange non-transparent electrodes in the frame area, whereby resistance can be reduced. As a result, the communication performance of the antenna can be improved.

### Modification Example 2

The following description describes Modification Example 2 of the present embodiment.

The same parts as those described above are denoted by the same reference numerals, and detailed descriptions of the same are omitted.

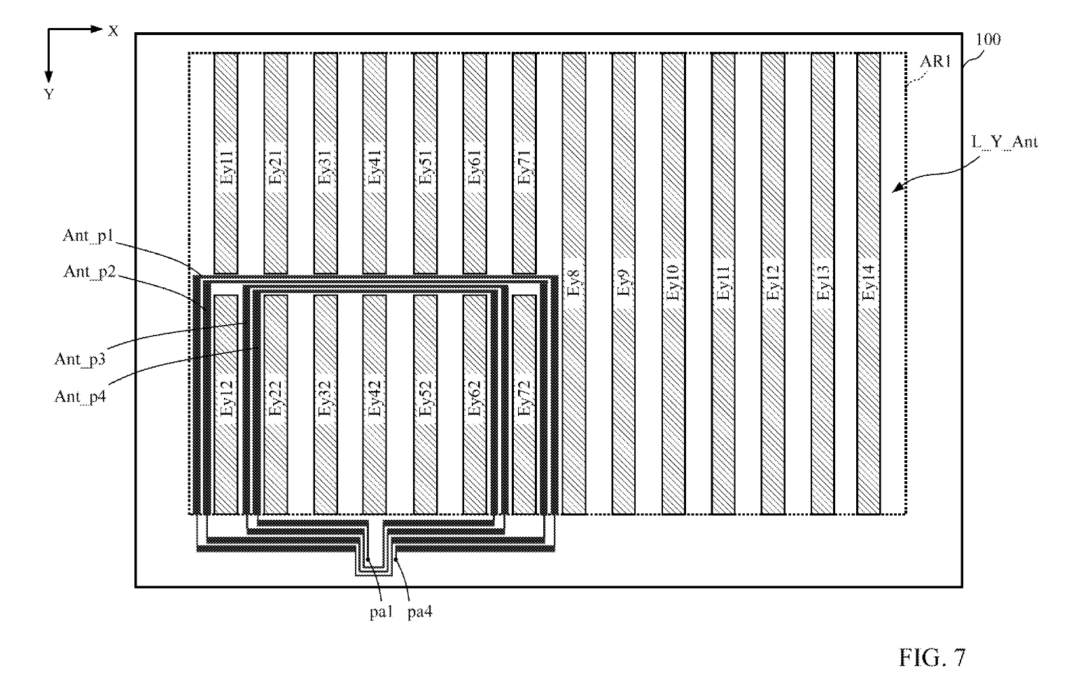

FIG. 7 is a plan view (a plan view when viewed from above the display surface) of a coexisting electrode layer L_Y_Ant of a touch-panel-equipped display device according to Modification Example 2.

The touch-panel-equipped display device of Modification Example 2, as illustrated in FIG. 7, has the same configuration as that of Embodiment 1 except that the Y-axis-direction electrode patterns Ey5 to Ey7 in the coexisting electrode layer L_Y_Ant are replaced with Y-axis-direction electrode patterns Ey51, Ey52, Ey61. Ey62, Ey71. Ey72.

The Y-axis-direction electrode patterns Ey51 and Ey52 are electrically connected to each other by a conducting line as is the case with Embodiment 1, and further, the same are connected to a terminal through which the touch panel controller TC1 outputs a signal for driving the Y-axis-direction electrode patterns Ey51 and Ey52 (a terminal of the touch panel controller TC1).

The Y-axis-direction electrode patterns Ey61 and Ey62 have a configuration identical to that described above, and so do the Y-axis-direction electrode patterns Ey71 and Ey72.

In the touch-panel-equipped display device of Modification Example 2, as illustrated in FIG. 7, antenna patterns Ant_p3, Ant_p4 are arranged so as to surround the Y-axis-direction electrode patterns Ey22 to Ey62, and the antenna patterns Ant_p1, Ant_p2 are arranged so as to surround the Y-axis-direction electrode patterns Ey12 to Ey72 and the antenna patterns Ant_p3, Ant_p4.

Further, in the touch-panel-equipped display device of Modification Example 2, eight antenna patterns extending in the X axis direction are formed in a frame area that is an area outside the area AR1 (the display surface AR1), as illustrated in FIG. 7.

In the touch-panel-equipped display device of Modification Example 2, the antenna patterns Ant_p1, Ant_p2, Ant_p3, Ant_p4 are connected by conducting lines as illustrated in FIG. 7, whereby a quadruple helical antenna pattern (four-turn helical antenna pattern) is formed.

Further, in the touch-panel-equipped display device of Modification Example 2, the terminals pa1, pa2 illustrated in FIG. 7 are connected to the matching unit 21.

In this way, in the touch-panel-equipped display device of Modification Example 2, a quadruple helical antenna pattern (four-turn helical antenna pattern) can be formed in the coexisting electrode layer L_Y_Ant.

### Modification Example 3

The following description describes Modification Example 3 of the present embodiment.

The same parts as those described above are denoted by the same reference numerals, and detailed descriptions of the same are omitted.

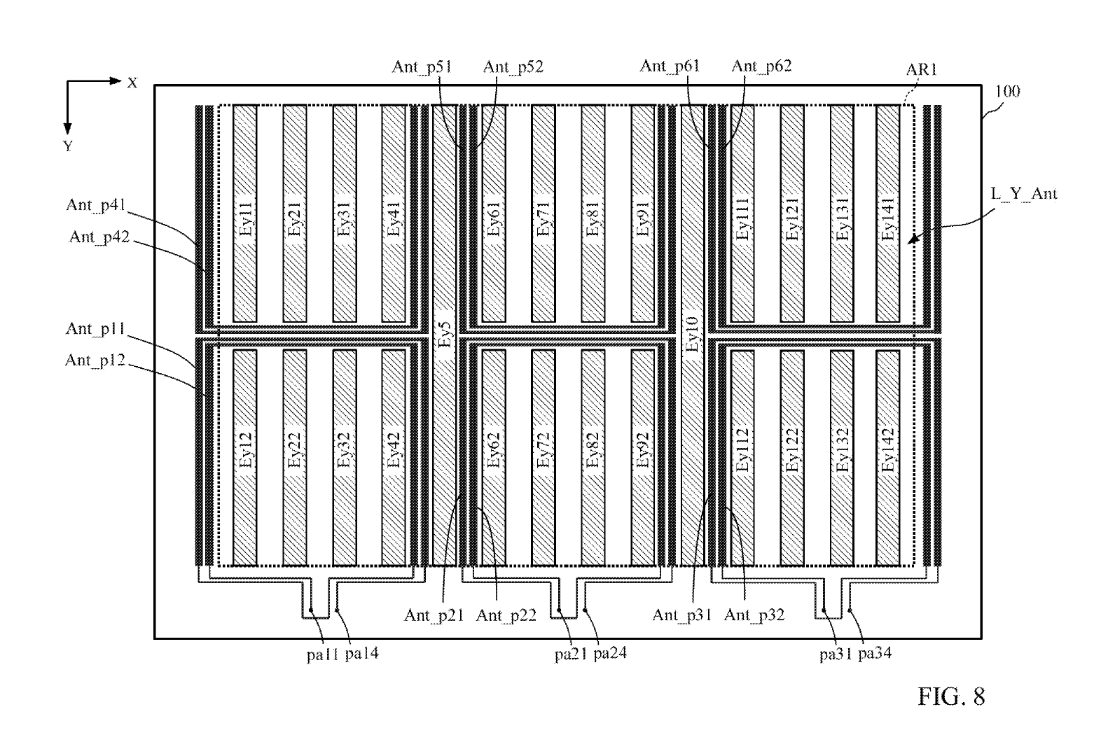

FIG. 8 is a plan view (a plan view when viewed from above the display surface) of a coexisting electrode layer L_Y_Ant of a touch-panel-equipped display device according to Modification Example 3.

The touch-panel-equipped display device of Modification Example 3, as illustrated in FIG. 8, has the same configuration as that of Embodiment 1 except that he Y-axis-direction electrode patterns Ey6 to Ey9 in the coexisting electrode layer L_Y_Ant in Embodiment 1 are replaced with Y-axis-direction electrode patterns Ey61 to Ey91, Ey62 to Ey92, and the Y-axis-direction electrode patterns Ey11 to Ey14 in the coexisting electrode layer L_Y_Ant in Embodiment 1 are replaced with Y-axis-direction electrode patterns Ey111 to Ey141, Ey112 to Ey142.

The Y-axis-direction electrode patterns Ey61 and Ey62 are electrically connected to each other by a conducting line as is the case with Embodiment 1, and further, the same are connected to a terminal through which the touch panel controller TC1 outputs a signal for driving the Y-axis-direction electrode patterns Ey61 and Ey62 (a terminal of the touch panel controller TC1).

The Y-axis-direction electrode patterns Ey71 and Ey72 have a configuration similar to that described above, and so do the Y-axis-direction electrode patterns Ey81 and Ey82, Ey91 and Ey92, Ey111 and Ey112, Ey121 and Ey122, Ey131 and Ey132, as well as Ey141 and Ey142.

In the touch-panel-equipped display device of Modification Example 3, further, as illustrated in FIG. 8, six antenna patterns each of which is to form a double helical antenna pattern (two-turn helical antenna pattern) are formed.

More specifically, in the touch-panel-equipped display device of Modification Example 3, the antenna pattern Ant_p12 is arranged so as to surround the Y-axis-direction electrode patterns Ey12 to Ey42, and the antenna pattern Ant_p11 is arranged so as to surround the Y-axis-direction electrode patterns Ey12 to Ey42 and the antenna pattern Ant_p12.

In the touch-panel-equipped display device of Modification Example 3 further, the antenna patterns Ant_p11, Ant_p12 are connected by a conducting line as illustrated in FIG. 8, whereby a double helical antenna pattern (two-turn helical antenna pattern) is formed. Terminals pa11, pa14 illustrated in FIG. 8 are connected to a matching unit (a function unit identical to the matching unit 21) for the antenna patterns Ant_p11, Ant_p12, and this matching unit is connected to an antenna driving unit (a function unit identical to the antenna driving unit 22) for the antenna patterns Ant_p11, Ant_p12.

Further, in the touch-panel-equipped display device of Modification Example 3, the antenna pattern Ant_p22 is arranged so as to surround the Y-axis-direction electrode patterns Ey62 to Ey92, and the antenna pattern Ant_p21 is arranged so as to surround the Y-axis-direction electrode patterns Ey62 to Ey92 and the antenna pattern Ant_p22.

In the touch-panel-equipped display device of Modification Example 3, further, the antenna patterns Ant_p21, Ant_p22 are connected by a conducting line as illustrated in FIG. 8, whereby a double helical antenna pattern (two-turn helical antenna pattern) is formed. Terminals pa21, pa24 illustrated in FIG. 8 are connected to a matching unit (a function unit identical to the matching unit 21) for the antenna patterns Ant_p21, Ant_p22, and this matching unit is connected to an antenna driving unit (a function unit identical to the antenna driving unit 22) for the antenna patterns Ant_p21, Ant_p22.

Further, in the touch-panel-equipped display device of Modification Example 3, the antenna pattern Ant_p32 is arranged so as to surround the Y-axis-direction electrode patterns Ey112 to Ey142, and the antenna pattern Ant_p31 is arranged so as to surround the Y-axis-direction electrode patterns Ey112 to Ey142 and the antenna pattern Ant_p32.

In the touch-panel-equipped display device of Modification Example 3, the antenna patterns Ant_p31, Ant_p32 are connected by a conducting line as illustrated in FIG. 8, whereby a double helical antenna pattern (two-turn helical antenna pattern) is formed. Terminals pa31, pa34 illustrated in FIG. 8 are connected to a matching unit (a function unit identical to the matching unit 21) for the antenna patterns Ant_p31, Ant_p32, and this matching unit is connected to an antenna driving unit (a function unit identical to the antenna driving unit 22) for the antenna patterns Ant_p31, Ant_p32.

In the touch-panel-equipped display device of Modification Example 3, further, the antenna patterns Ant_p41, Ant_p42, the antenna patterns Ant Ant_p52, and, the antenna patterns Ant_p61, Ant_p62 are configured in the same manner as described above, whereby double helical antenna patterns (two-turn helical antenna patterns) are formed.

In this way, in the touch-panel-equipped display device of Modification Example 3, as illustrated in FIG. 8, a plurality (six in FIG. 8) of quadruple helical antenna patterns (four-turn helical antenna patterns) can be formed in the coexisting electrode layer L_Y_Ant.

### Modification Example 4

The following description describes Modification Example 4 of the present embodiment.

The same parts as those described above are denoted by the same reference numerals, and detailed descriptions of the same are omitted.

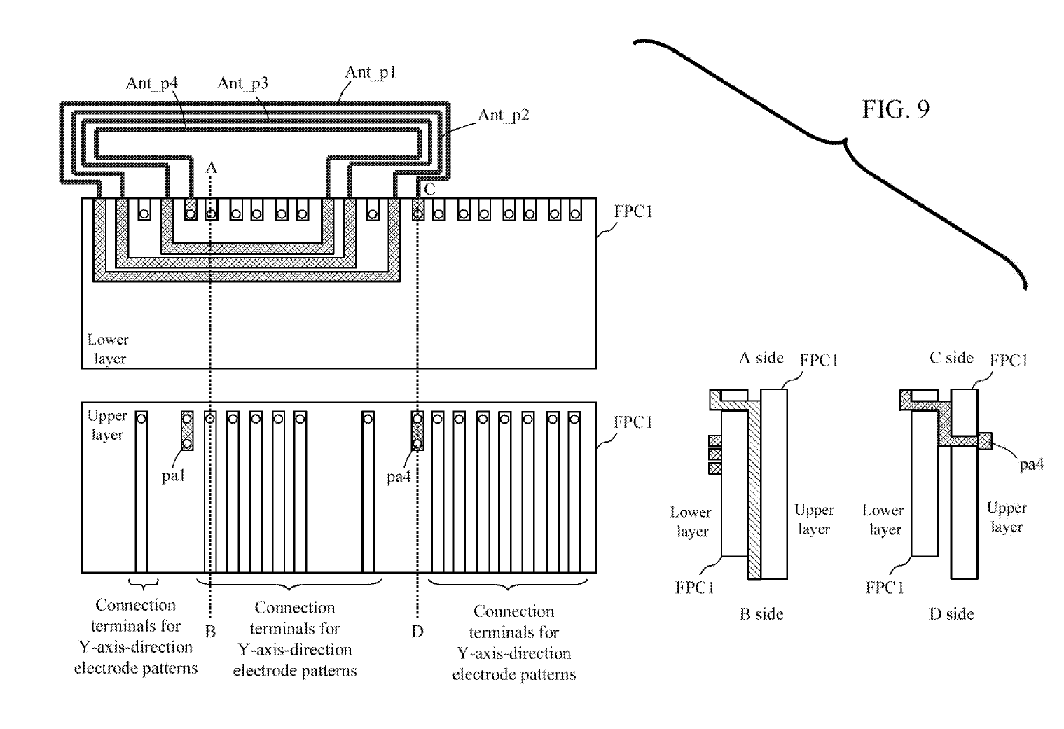

The left diagram in FIG. 9 illustrates a schematic configuration of antenna patterns Ant_p1, Ant_p2, Ant_p3, Ant_p4 formed in a coexisting electrode layer L_Y_Ant of a touch-panel-equipped display, device of Modification Example 4,and a flexible printed substrate FPC1 having a two-layer structure. The right diagram in FIG. 9 illustrates a cross-sectional view taken along line A-B in the eft diagram in FIG. 9, and a cross-sectional view taken along line C-D in the left diagram in FIG. 9. Parts indicated by circles in FIG. 9 are through holes that go from the upper layer to the lower layer in the flexible printed substrate FPC1 of the two-layer structure.

In the touch-panel-equipped display device of Modification Example 4, terminals are connected by conductive patterns indicated by cross-hatching in the left diagram in FIG. 9, and further, end points pa1, pa2 illustrated in the left diagram in FIG. 9 are connected to the matching unit 21, whereby a quadruple helical antenna pattern (four-turn helical antenna pattern) can be formed.

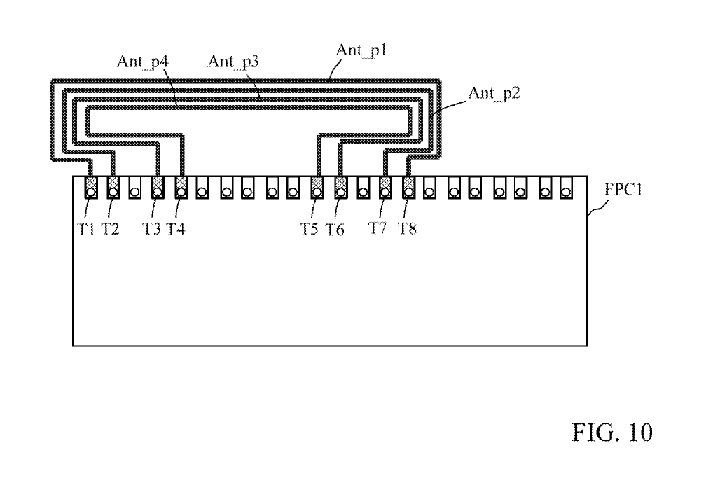

Alternatively, in the touch-panel-equipped display device of Modification Example 4, the shape of the antenna may be changed by changing the connection of terminals T1 to T8 for connection with the antenna pattern illustrated in FIG. 10.

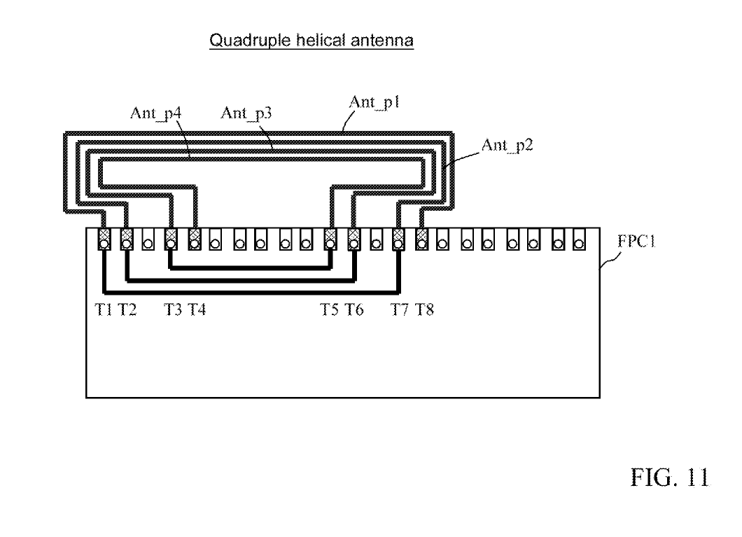

(1) In a case where an antenna of a quadruple helical structure is to be formed in the touch-panel-equipped display device of Modification Example 4, the terminal T1 and the terminal T7 are connected to each other, the terminal T2 and the terminal T6 are connected to each other, the terminal T3 and the terminal T6 are connected to each other, and further, the terminals T4, T8 are connected to the matching unit 21, as illustrated in FIG. 11. With this configuration, an antenna of a quadruple helical structure can be formed in the touch-panel-equipped display device of Modification Example 4.

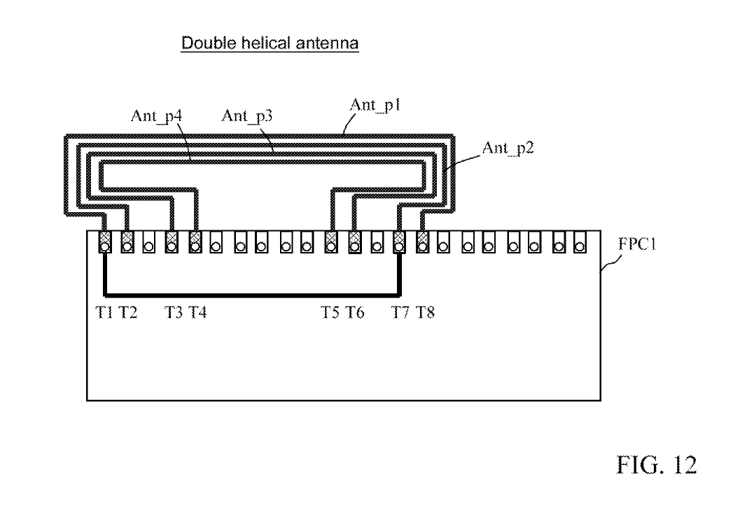

(2) In a case where an antenna of a double helical structure is to be formed in the touch-panel-equipped display device of Modification Example 4, the terminal T1 and the terminal T7 are connected to each other, and the terminals T2, T8 are connected to the matching unit 21, as illustrated in FIG. 12. With this configuration an antenna of a double helical structure can be formed in the touch-panel-equipped display device of Modification Example 4.

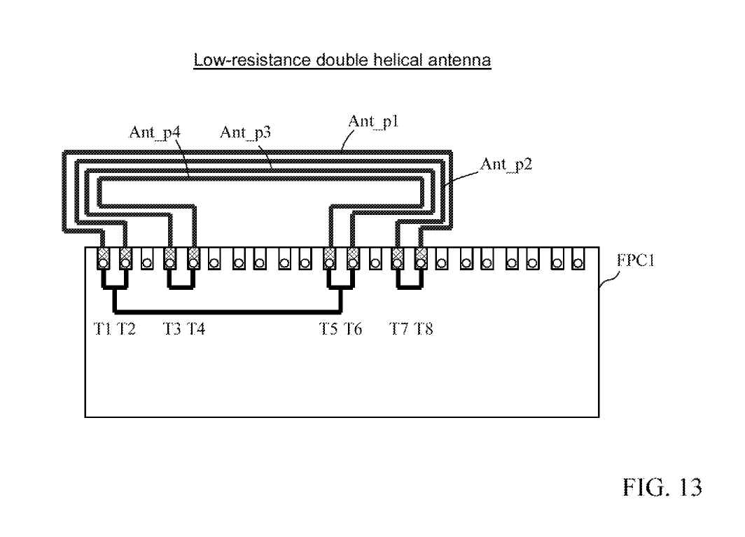

(3) In a case where an antenna of a low-resistance double helical structure is to be formed in the touch-panel-equipped display device of Modification Example 4, the terminals T1, T2, T5, T6 are connected, the terminals T3 and T4 are connected to each other, the terminals T7 and T8 are connected to each other, and further, the terminals T4, T8 are connected to the matching unit 21, as illustrated in FIG. 13. With this configuration, an antenna of a low-resistance double helical structure can be formed in the touch-panel-equipped display device of Modification Example 4. In other words, in this case, an antenna pattern of a double helical structure having a greater antenna pattern width can be formed. It is therefore possible to reduce the resistance, as compared with an antenna pattern of a single helical structure.

As described above, in the touch-panel-equipped display device of Modification Example 4, a variety of antenna patterns can be realized by changing the connection of terminals of the flexible printed substrate FPC1.

In the touch-panel-equipped display device, properties (resonance frequency, etc.) of an antenna are sometimes caused to shift by the electrode structure of the display itself, mutual interactions between the display and the display housing (addition of electric capacitance, generation of mutual inductance, etc.), depending on the type of the display panel DP mounted thereon, individual difference, etc. Further, in a case where antennas are provided at a plurality of locations, the properties (resonance frequency, etc.) of antennas vary with the locations in some cases. To cope with this, the touch-panel-equipped display device has a structure with which the own performance of the antenna can be varied as described above, whereby the antenna performance can be adjusted as required.

### Modification Example 5

The following description describes Modification Example 5 of the present embodiment.

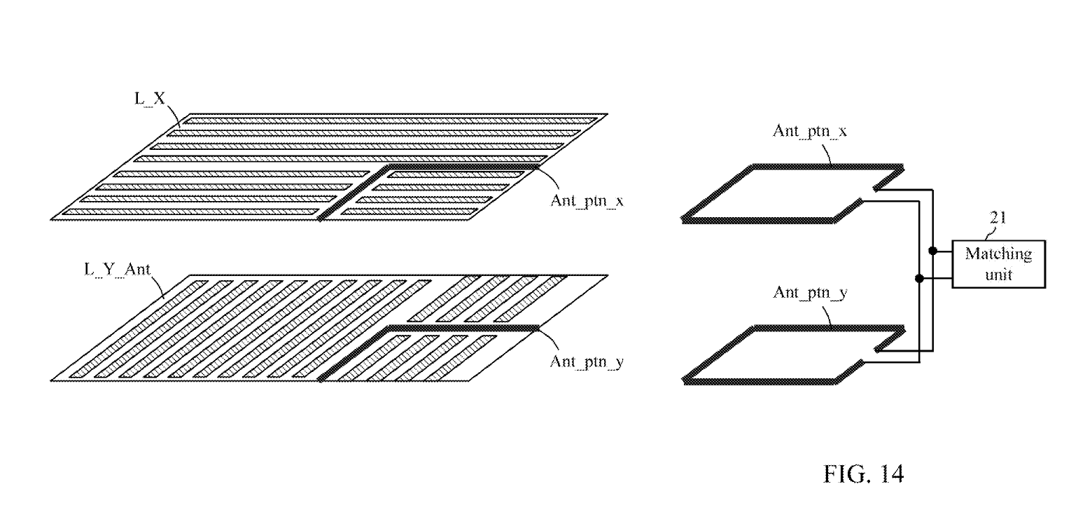

FIG. 14 is a perspective view illustrating a schematic configuration of an X-axis-direction electrode layer L_X and a coexisting conductive layer L_Y_Ant in a touch-panel-equipped display device of Modification Example 5 (left diagram of FIG. 14). Further, the right diagram of FIG. 14 illustrates a schematic configuration of an antenna pattern Ant_ptn_x formed in the X-axis-direction electrode layer L_X, an antenna pattern Ant_ptn_y formed in the coexisting conductive layer L_Y_Ant, and a matching unit 21 in the touch-pane;-equipped display device of Modification Example 5.

In the touch-panel-equipped display device of the present modification example, as illustrated in FIG. 14, a part of X-axis-direction electrodes are divided in the X-axis-direction electrode layer L_X as well, and the antenna pattern Ant_ptn_x is formed between the pieces thus obtained by dividing the X-axis-direction electrodes. In the frame area as well, an antenna pattern is formed, and this antenna pattern and the antenna pattern Ant_ptn_x compose a loop antenna as illustrated in the right diagram of FIG. 14.

In the touch-panel-equipped display device of the present modification example, as illustrated in FIG. 14, a part of the Y-axis-direction electrodes are divided in the coexisting conductive layer L_Y_Ant, as is the case with the above-described case, and an antenna pattern Ant_ptn_y is formed between the pieces thus obtained by dividing the Y-axis-direction electrodes. In the frame area as well, an antenna pattern is formed, and this antenna pattern and the antenna pattern Ant_ptn_y compose a loop antenna as illustrated in the right diagram of FIG. 14.

In the touch-panel-equipped display device of the present modification example, the antenna patterns having a configuration as described above are connected with the matching unit 21, as illustrated in the right diagram of FIG. 14.

In this way, in the touch-panel-equipped display device of the present modification example, as illustrated in FIG. 14, antenna electrodes (antenna patterns) are provided so as to be arranged among both of the X electrodes and the Y electrodes for touch panel. This configuration allows the layers of the antenna electrodes (antenna patterns) to increase from a single layer to two layers, thereby making it possible to reduce resistance. As a result, in the touch-panel-equipped display device of the present modification example, the communication performance of the antenna can be improved.

Besides, in the touch-panel-equipped display device of the present modification example, the antenna pattern Ant_ptn_x in the X-axis-direction electrode layer L_X and the antenna pattern Ant_ptn_y in the coexisting conductive layer L_Y_Ant are formed at such positions that the same overlap with each other when viewed in a plan view, as illustrated in FIG. 14. This results in that any touch panel electrode (electrode pattern for touch panel) never covers an antenna electrode (antenna pattern). For this reason, in the touch-panel-equipped display device of the present modification example, an inductance component like the inductance component Ltx in the equivalent circuit in FIG. 5 is not included, and therefore, the parasitic capacitance decreases and the absorption of a magnetic field is reduced as well. As a result, in the touch-panel-equipped display device of the present modification example, the communication performance of the antenna can be improved.

### Modification Example 6

The following description describes Modification Example 6 of the preset embodiment.

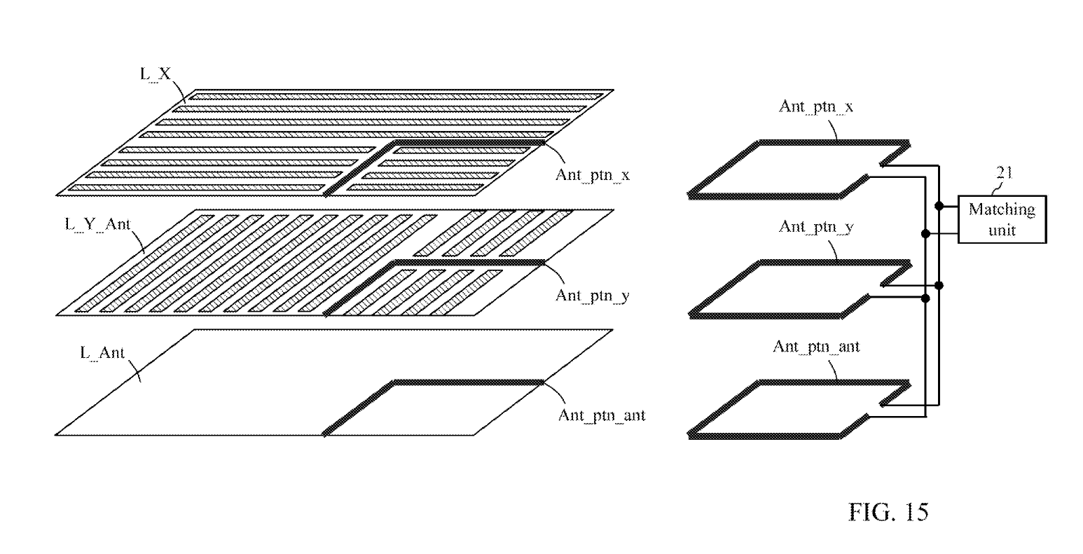

FIG. 15 illustrates a perspective view (left diagram of FIG. 15) illustrating a schematic configuration of an X-axis-direction electrode layer L_X, a coexisting conductive layer L_Y_Ant, and an antenna layer L_Ant in a touch-panel-equipped display device of Modification Example 6. Further, the right diagram of FIG. 15 illustrates a schematic configuration of an antenna pattern Ant_ptn_x formed in the X-axis-direction electrode layer an antenna pattern Ant_ptn_y formed in the coexisting conductive layer L_Y_Ant, an antenna pattern Ant_ptn_ant formed in the antenna layer L_Ant, and a matching unit 21 in the touch-panel-equipped display device of Modification Example 6.

In the touch-panel-equipped display device of the present modification example, as illustrated in FIG. 15, a part of X-axis-direction electrodes in the X-axis-direction electrode layer are also divided, and the antenna pattern Ant_ptn_x is formed between the pieces thus obtained by dividing the X-axis-direction electrodes. In the frame area as well, an antenna pattern is formed, and this antenna pattern and the antenna pattern Ant_ptn_x compose a loop antenna as illustrated in the right diagram of FIG. 15.

In the touch-panel-equipped display device of the present modification example, as illustrated in FIG. 15, a part of the Y-axis-direction electrodes are divided in the coexisting conductive layer L_Y_Ant, as is the case with the above-described case, and the antenna pattern Ant_ptn_y is formed between the pieces thus obtained by dividing the Y-axis-direction electrodes. In the frame area as well, an antenna pattern is formed, and this antenna pattern and the antenna pattern Ant_ptn_y compose a loop antenna as illustrated in the right diagram of FIG. 14.

Besides, in the touch-panel-equipped display device of the present modification example, as illustrated in FIG. 15, the antenna layer L_Ant is provided additionally, and the antenna pattern Ant_ptn_ant is formed in the antenna layer L_Ant. In the frame area as well, an antenna pattern is formed, and this antenna pattern and the antenna pattern Ant_ptn_ant compose a loop antenna as illustrated in the right diagram of FIG. 15.

In the touch-panel-equipped display device of the present modification example, the antenna pattern having a configuration as described above is connected with the matching unit 21, as illustrated in the right diagram of FIG. 15.

In this way, in the touch-panel-equipped display device of the present modification example, as illustrated in FIG. 15, antenna electrodes (antenna patter are provided so as to be arranged among both of the X electrodes and the Y electrodes for touch panel. This configuration allows the layers of the antenna electrodes (antenna patterns) to increase from a single layer to three layers, thereby making it possible to reduce resistance. As a result, in the touch-panel-equipped display dev of the present modification example, the communication performance of the antenna can be improved.

Besides, in the touch-panel-equipped display device of the present modification example, the antenna pattern Ant_ptn_x in the X-axis-direction electrode layer L_X, the antenna pattern Ant_ptn_y in the coexisting conductive layer L_Y_Ant, and the antenna pattern Ant_ptn_ant in the antenna layer L_Ant are formed at such positions that these overlap with one another when viewed in a plan view, as illustrated in FIG. 15. This results in that any touch panel electrode (electrode pattern for touch panel) never covers an antenna electrode (antenna pattern). For this reason, in the touch-panel-equipped display device of the present modification example, an inductance component like the inductance component Ltx in the equivalent circuit in FIG. 5 is not included, and therefore, the parasitic capacitance decreases, and the absorption of a magnetic field is reduced as well. As a result, in the touch-panel-equipped display device of the present modification example, the communication performance of the antenna can be improved.

### Other Embodiments

The touch-panel-equipped display devices of the above-described embodiments (including the modification examples) are described with reference to examples in which a layer in which antenna patterns and Y-axis-direction electrode patterns for touch panel coexist is provided, but the configuration is not limited to this. Alternatively, the configuration may be such that a layer in which antenna patterns and an X-axis-direction electrode pattern for touch panel coexist is provided.

Alternatively, antenna patterns may be formed in both of the layer in which the X-axis-direction electrode patterns for touch panel are formed, and the layer in which the Y-axis-direction electrode patterns for touch panel are formed.

Further alternatively, a touch-panel-equipped display device may be realized by combining a part or all of the above-described embodiments (including the modification examples).

Further, in the foregoing description, only principal and essential members are indicated in a simplified manner, among the constituent members required for the above-described embodiments. The configurations of the above-described embodiments may include arbitrary constituent members that are not clearly indicated in the foregoing description of the embodiments. Besides, in the embodiments and the drawings, the size and dimension ratio, etc., of each member do not necessarily represent an actual size, an actual dimension ratio, and the like faithfully. The size, the dimension ratio, and the like, therefore, can be varied without departing from the spirit and scope of the present invention.

The specific configuration of the present invention is not limited to those of the above-described embodiments, and it can be changed or corrected variously without departing from the spirit and scope of the invention.

### [Note]

The present invention can be also described as follows.

The first invention is a device for touch panel that includes electrode layer and a second electrode layer.

The first electrode layer includes a first sensor electrode pattern for touch panel and a first antenna pattern.

The second electrode layer includes a second sensor electrode pattern for touch panel that is arranged so as to intersect with the first sensor electrode pattern when viewed in a plan view.

In this device for touch panel, the first sensor electrode pattern for touch panel and the first antenna pattern are provided in the first electrode layer. This makes it possible to suppress eddy current generated between an antenna and a touch sensor (electrodes for touch panel), as compared with a case where the prior art is applied. As a result, in this device for touch panel, the deterioration of the performance of the antenna due to eddy current generated between the antenna and the touch sensor (electrodes for touch panel) can be prevented, as compared with a case where the prior art is applied.

Further, in the device for touch panel, since the first sensor electrode pattern for touch panel and the first antenna pattern are provided, it is unnecessary to additionally provide a layer in which the first sensor electrode pattern is to be formed. Therefore, it is possible to reduce the manufacturing cost.

The second invention is the first invention further characterized in that the first sensor electrode pattern includes N first direction electrode patterns (N: natural number). Each of K first direction electrode patterns (K: natural number, K<N), of the N first direction electrode patterns, includes a first conductive pattern and a second conductive pattern that is arranged separately from the first conductive pattern.

Herewith, in this device for touch panel, an area for arranging a conductive pattern other than the first direction electrode pattern can be ensured in the first electrode layer.

The third invention is the second invention further characterized in that at least a part of the first antenna pattern is arranged in an area between the first conductive pattern and the second conductive pattern.

Herewith, in this device for touch panel, at least a part of the first antenna pattern can be arranged in an area between the first conductive pattern and a second conductive pattern in the first electrode layer.

The fourth invention is any one of the first to third inventions further characterized in that a part of the first antenna pattern is arranged in an area other than a touch panel area in which the first sensor electrode pattern and the second sensor electrode pattern are arranged when viewed in a plan view.

Herewith, in this device for touch panel, the first antenna pattern can be formed an area other than the touch panel area (for example, a frame area).

The fifth invention is any one of the first to fourth inventions further characterized in that the first antenna pattern is arranged so as to form a helical antenna when viewed in a plan view.

Herewith, in this device for touch panel, a helical antenna can be formed.

The sixth invention is the fifth invention further characterized in that the first antenna pattern is arranged so as to form a helical antenna of a plurality of turns when viewed in a plan view.

Herewith, in this device for panel, a helical antenna of a plurality of turns can be farmed.

The seventh invention is any one of the first to sixth inventions further including an electrode lead-out part that includes terminals for connecting the first sensor electrode pattern for touch panel and the first antenna pattern, wherein the shape of the antenna formed with the fiat antenna pattern is changed by changing line layout between the terminals of the electrode lead-out part.

Herewith, in this device for touch panel, a variety of antenna patterns can be formed, whereby antennas with a variety of antenna properties can be realized.

The eight invention is the seventh invention further characterized in that the electrode lead-out part is formed with a flexible printed substrate.

Herewith, in this device for touch panel, an electrode lead-out part can be realized by using a flexible printed substrate.

The ninth invention is any one of the first to eighth inventions further including an GND area that is provided in the same layer as the layer where the first antenna pattern is formed, so that the GND area is arranged along at least a part of the first antenna pattern when viewed in a plan view.

Herewith, in this device for touch panel, influences of an electromagnet field, disturbance noise, etc. excreted to the first antenna pattern can be suppressed, whereby the antenna performance can be improved.

The configuration may be such that, in an area for the “GND area”, for example, a mesh pattern made of thin metal lines is formed and the mesh pattern is connected to a GND potential so that a “GND area” is realized.

The tenth invention is any one of the first to eighth inventions further including GND areas that are provided in the same layer as the layer where the first antenna pattern is formed, so that at least a part of the first antenna pattern is interposed between the GND areas when viewed in a plan view.

Herewith, in this device for touch panel, influences of an electromagnetic field, disturbance noise, etc. exerted to the first antenna pattern can be suppressed, whereby the antenna performance can be improved.

The configuration may be such t in an area for the “GND area”, for example, a mesh pattern made of thin metal lines is formed and the mesh pattern is connected to a GND potential so that a “GND area” is realized.

The eleventh invention is any one of the first to tenth inventions further including a dummy pattern provided in an area in which none of the electrode pattern and the first antenna pattern is formed, in at least one of the first electrode layer and second electrode layer.

Herewith, in this device for touch panel, influences of an electromagnetic field, disturbance noise, etc. exerted to the first antenna pattern can be suppressed, whereby the antenna performance can be improved. Further, in this device for touch panel, the transmittance is made uniform in the entire surface (the entire display surface) by providing a dummy pattern, and the electrode patterns for touch panel and the electrode patterns for antenna are appropriately prevented from being visit le when a user looks at the display surface.

The twelfth invention is the eleventh invention further characterized in that the dummy pattern is connected to x GND potential.

The thirteenth invention is the second invention further characterized in that, among the first sensor electrode patterns, the first sensor electrode pattern that includes neither the first conductive pattern nor the second conductive pattern is formed so that the width of the first sensor electrode pattern in an overlap area that is an area overlapping the second sensor electrode pattern arranged in a spacing area that is an area between the first conductive pattern and the second conductive pattern is smaller than a width of the first sensor electrode pattern in an area other than the overlap area, when viewed in a plan view.

Herewith, in this device for touch panel, it is possible to appropriately prevent differences in the intersection capacitances between the X-axis-direction electrode patterns and the Y-axis-direction electrode patterns for touch panel from increasing.

The fourteenth invention is any one of the first to thirteenth inventions further characterized in that the second electrode layer includes'second antenna pattern.

Herewith, he antenna pattern can be included n the second electrode layer.

The fifteenth invention is the fourteenth invention further characterized in that the second antenna pattern is provided so as to at least partially overlap the first antenna pattern when viewed in a plan view.

Herewith, in this device for touch panel, a part of the touch panel electrode (electrode pattern for touch panel) that covers the antenna electrode (antenna pattern) can be decreased. In this device for touch panel, therefore, an inductance component generated when a touch panel electrode (electrode pattern for touch panel) overlaps an antenna electrode (antenna pattern) can be reduced. As a result, in the device for touch panel, the communication performance of the antenna can be improved.

The sixteenth invention is any one of the first to fifteenth inventions further including an antenna layer that includes a third antenna pattern.

The seventeenth invention is the sixteenth invention further characterized in that the third antenna pattern is provided so as to At least partially overlap the first antenna pattern when viewed in a plan view.

Herewith, in this device for touch panel, a part of the touch panel electrode (electrode pattern for touch panel) that covers the antenna electrode (antenna pattern) can be decreased. In this device for touch panel, therefore, an inductance component generated when a touch panel electrode (electrode pattern for touch panel) overlaps an antenna electrode (antenna pattern) can be reduced. As a result, in the device for touch panel, the communication performance of the antenna can be improved. Besides, by connecting the first antenna pattern and the third antenna pattern in parallel, the resistance can be reduced.

The eighteenth invention is the fourteenth or fifteenth invention further including an antenna layer that includes a third antenna pattern.

The third antenna pattern is provided so as to at least partially overlap the first antenna pattern and the second antenna pattern when viewed in a plan view.

Herewith, in this device for touch pan a part of the touch panel electrode (electrode pattern for touch panel) that covers the antenna electrode (antenna pattern) can be decreased. In this device for touch panel, therefore, an inductance component generated when a touch panel electrode (electrode pattern for touch panel) overlaps an antenna electrode (antenna pattern) can be reduced. As a result, in the device for touch panel, the communication performance of the antenna can be improved. Further, by connecting the first antenna pattern, the second antenna pattern, and the third antenna pattern in parallel, the resistance can be reduced.

### INDUSTRIAL APPLICABILITY

The present invention makes it possible to realize, a device for touch panel characterized in that the deterioration, of the performance of an antenna caused by eddy current generated between the antenna and a touch sensor (electrode for touch panel) can be prevented, and the manufacturing cost can be reduced. The present invention, therefore, is useful in the field of touch panel-related industry, and can be implemented in this field.

### DESCRIPTION OF REFERENCE NUMERALS

100: touch-pane;-equipped display device (device for touch panel)
1: case
2: circuit part
21: matching unit
22: antenna driving unit
DP: display pan&
L_Y_Ant: coexisting conductive layer
L_X: X-axis-direction electrode layer

1. A device for touch panel comprising:
a first electrode layer that includes a first sensor electrode pattern for touch panel and a first antenna pattern; and
a second electrode layer that includes a second sensor electrode pattern for touch panel that is arranged so as to intersect with the first sensor electrode pattern when viewed in a plan view.

2. The device for touch panel according to claim 1,
wherein the first sensor electrode pattern includes N first direction electrode patterns (N: natural number), and
each of K first direction electrode patterns (K: natural number, K<:N), of the N first direction electrode patterns, includes a first conductive pattern and a second conductive pattern that is arranged separately from the first conductive pattern.

3. The device for touch panel according to claim 2,
wherein at least a part of the first antenna pattern is arranged in an area between the first conductive pattern and the second conductive pattern.

4. The device for touch panel according to claim 1,
wherein a part of the first antenna pattern is arranged in an area other than a touch panel area in which the first sensor electrode pattern and the second sensor electrode pattern are arranged, when viewed in a plan view.

5. The device tor touch panel according to claim 1,
wherein the first antenna pattern is arranged so as to form a helical antenna when viewed in a plan view.

6. The device for touch panel according to claim 5,
wherein the first antenna pattern is arranged so as to form a helical antenna of a plurality of turns when viewed in a plan view.

7. The device for ouch panel according to claim 1, further comprising:
an electrode lead-out part that includes terminals for connecting the first sensor electrode pattern for touch panel and the first antenna pattern
wherein a shape of the antenna formed with the first antenna pattern is changed by changing line layout between the terminals of the electrode lead-out part.

8. The device for touch panel according to claim 7,
wherein the electrode lead-out part is formed with a flexible printed substrate.

9. The device for touch panel according to claim 1, further comprising:
an GND area that is provided in the same layer as the layer where the first antenna pattern is formed, so that the GND area is arranged along at least a part of the first antenna pattern when viewed in a plan view.

10. The device for touch panel according to claim 1, further comprising:
GND areas that are provided in the same layer as the layer where the first antenna pattern is formed, so that at least a part of the first antenna pattern is interposed between the CND areas when viewed in a plan view.

11. The device for touch panel according to claim 1, further comprising:
a dummy pattern provided in an area in which none of the electrode pattern and the first antenna pattern is formed, in at least one of the first electrode layer and second electrode layer.

12. The device for touch panel according to claim 11,
wherein the dummy pattern is connected to a GND potential.

13. The device for touch panel according to claim 2,
wherein, among the first sensor electrode patterns, the first sensor electrode pattern that includes neither the first conductive pattern nor the second conductive pattern is formed so that a width of the first sensor electrode pattern in an overlap area that is an area overlapping the second sensor electrode pattern arranged in a spacing area that is an area between the first conductive pattern and the second conductive pattern is smaller than a width of the first sensor electrode pattern in an area other than the overlap area, when viewed in a plan view.

14. The device for touch panel according to claim 1,
wherein the second electrode layer includes a second antenna pa

15. The device for touch panel according to claim 14,
wherein the second antenna pattern is provided so as to at least partially overlap the first antenna pattern when viewed in a plan view.

16. The device for touch panel according to claim 1, further comprising an antenna layer that includes a third antenna pattern.

17. The device for touch panel according to claim 16,
wherein the third antenna pattern is provided so as to at least partially overlap the first antenna pattern when viewed in a plan view.

18. The device for ouch panel according to claim 14, further comprising an antenna layer that includes a third antenna pattern,
wherein the third antenna pattern is provided so as to at least partially overlap the first antenna pattern and the second antenna pattern when viewed in a plan view.
